(19) United States
(12) Patent Application Publication
(10) Pub. No.: US 2015/0176151 A1
(43) Pub. Date: Jun. 25, 2015

(54) SYSTEM AND METHOD FOR FORMING A SILICON WAFER

(71) Applicant: Energy Materials Research, LLC, Holly, MI (US)

(72) Inventor: Carl E. Bleil, Rochester Hills, MI (US)

(73) Assignee: Energy Materials Research, LLC, Holly, MI (US)

(21) Appl. No.: 14/136,296

(22) Filed: Dec. 20, 2013

(51) Int. Cl. C30B 15/16; C30B 15/00; C30B 15/06

(52) U.S. Cl. CPC C30B 15/16; C30B 15/06; C30B 15/002

(57) ABSTRACT

An apparatus for forming a crystalline ribbon from molten silicon having a silicon ribbon support. A heater is provided including a pair of spaced planar electrodes parallel to the surface of the molten silicon for capacitively coupling radio frequency electrical currents into the material causing a ribbon of material to melt along a zone. A conductive electrode in thermal contact with a respective cooler and a dielectric layer between the conductive and semi-conductive electrodes is provided. A controller configured to control the removal of heat from the melted ribbon of material in a direction substantially perpendicular to the surface of the molten silicon to effect crystal growth, and to control the fluid level of the material in the crucible.

### FIELD

The present disclosure relates to a system and method to form a crystal and, more particularly, to a system and method to supply liquid silicon to a system which forms a silicon crystal ribbon.

### BACKGROUND

This section provides background information related to the present disclosure that is not necessarily prior art. There is a need for thin crystalline ribbons and films of many materials such as silicon and other semiconductors. These ribbons are often very costly and difficult to produce. For example, thin wafers of monocrystalline semiconductor materials are generally produced from monocrystalline boules grown by the Czochralski technique. The preparation of the thin wafers from large single crystal boules requires slicing and polishing, is a costly and time consuming technique, and inherently wastes much of the single crystal unprocessed material.

Consequently, much effort has been directed toward growing thin monocrystalline ribbons that need only be scribed and broken to be used. Crystal ribbons have been grown from a melt in a crucible where a heater is positioned below the melt surface, a heat sink is positioned above the melt surface, and the ribbon is pulled horizontally from the surface of the melt. This technique produces single crystal ribbons much faster than the previous methods. However, pulling a ribbon too quickly or at too great an angle from horizontal introduces grain boundaries and imperfections that degrade the performance of circuitry placed on the semiconductor surface. Further, crystal ribbon width has been limited, thus decreasing the usefulness of the ribbons. Moreover, the necessary controls to implement the process and produce very thin crystal ribbons and films of good quality are difficult to manage and thus the commercial advantage is reduced.

While ribbon growth has been demonstrated for a given material using the techniques disclosed in the prior art, it has become apparent that improvements in the control of the process would lead to more reliable operation, extension to other materials, wide ribbons and a better product. For example, there is a tendency for dendritic structures to form in the created ribbons. It has been suggested that a low axial temperature gradient in the ribbon is necessary to prevent dendritic growth.

### SUMMARY

This section provides a general summary of the disclosure, and is not a comprehensive disclosure of its full scope or all of its features. It is, therefore, an object of the teachings to provide a method and apparatus for improved temperature control and fluid flow in the growth of crystalline ribbon from a source of liquid material.

The apparatus for forming a crystalline ribbon from source material has first and second heating electrodes associated with a crucible configured to hold molten silicon. The crucible has a formation portion having a flange member that supports and holds liquid silicon between the flange and the crystalline ribbon. This system includes a mechanism to provide new material to the crucible without disturbing the ongoing ribbon processing. The melting of the source material is controlled by a processor that maintains the operating melt level and provides a safety action to prevent equipment destruction in the case of heating or process failure.

According to the present teachings, the system described above further has a selected atmosphere surrounding the ribbon growth that is not disruptively modified upon the addition of new material to the crucible. Further, solid material in transformed to a liquid prior to moving the source material to the crucible.

According to the present teachings, to accomplish continuous single crystal growth with the desired crystal orientation, periodic detection of the crystal's orientation is preferred and corrections applied as needed. Precise rotation of the growing ribbon about the pull axis may be accomplished with continuous thermal leveling. Rotation about a vertical axis may be accomplished during growth, with adjustments to a pulling mechanism if needed.

According to another teaching, the system as described above can include an optical mechanism to monitor the tip of the crystal for defects caused by random nucleation. The system can further include a frequency stabilization circuit to control the growth rate and meniscus at the crystal tip.

The teachings are carried out in a method of growing a crystal ribbon from source material having the steps of electrically heating a body of liquid source material to form and maintain a ribbon floating on molten source material, the ribbon has surfaces coplanar with the desired crystal film via electrodes which are displaced from the film and the molten source material, heating the source material by selectively applying a radiofrequency signal to the source material, cooling the other surface of the film to effect ribbon growth wherein the combined heating and cooling steps control the temperature gradient in the film normal to an angled film growth surface, and moving the ribbon on the liquid surface in an axial direction away from the liquid source as the film grows.

The teachings are further carried out by apparatus for forming a crystalline ribbon from source material having a film of material that floats on a liquid material surface in a plane, a first heater having a pair of RF electrodes spaced apart from the film in capacitive conductive relation to the film, and a controller for controlling the electrodes to maintain the liquid at a temperature just above the melting point of the material. The controller regulates initially heating the material and subsequently stabilizing the temperature of a liquid surface adjacent the film liquid growth interface. A second heater melts and maintains the temperature of the source of material. The first heater includes a planar electrode parallel to the ribbon plane for capacitively coupling radio frequency electrical currents into the liquid material, causing a film of material to melt along a solid-liquid interface zone incorporated in the source body.

According to alternate teachings, a controller is provided which uses a transmitted RF energy to liquid silicon below a mono-crystalline ribbon. A cooler having an angled reflective surface is provided for removing heat from the surface of the liquid silicon in a direction substantially perpendicular to the plane, to effect ribbon growth and form a crystalline film of material. An actuator causes relative motion to the crystal ribbon parallel to a plane between the ribbon and the heater.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 represents a side sectional view of an apparatus for forming a silicon ribbon according to the present teachings;

FIG. 2 represents a top view of the apparatus shown in FIG. 1 with the RF heater removed;

FIG. 3 represents a top view of the apparatus shown in FIG. 2 with the crucible and the RF heater removed;

FIGS. 4a and 4b represent top and side views of a crucible according to the present teachings;

FIGS. 5a and 5b represent top and side views of a crucible according to the present teachings;

FIG. 6 represents a perspective view of the crucible shown in FIGS. 5a and 5b;

FIGS. 7 and 8 represent sectional views of an apparatus according to the teachings of the present invention. Corresponding reference numerals indicate corresponding parts throughout the several views of the drawings.

### DETAILED DESCRIPTION

While the description below is directed to a development for growing mono-crystalline ribbons of silicon, it will be recognized that it applies, with suitable modification, to other materials such as germanium and bismuth. For such materials, the molten state of the substance has substantially higher electrical conductivity than the solid state, and the surface tension between the liquid and solid is adequate to sustain a short unsupported molten zone.

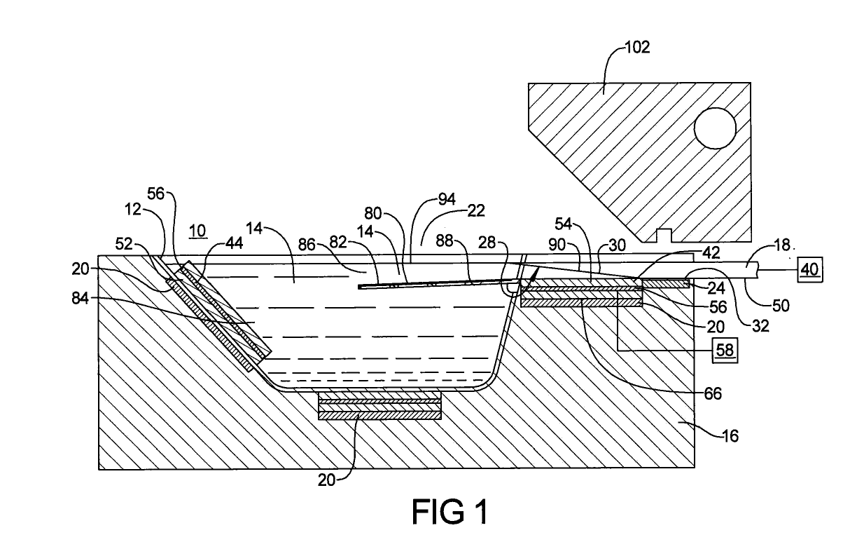

A cross section of the apparatus 10 for forming a mono-crystal ribbon is shown in FIG. 1. The apparatus 10 provides a crucible 12 for holding molten silicon 14 and a support structure 16 that supports the crucible 12 and a plurality of associated heaters 20. As further described below, a mono-crystal 18 is formed at a location generally at the melt level in the crucible 12. The mono-crystal 18 floats on the surface of the molten silicon 14 and is slowly drawn off of the molten silicon 14 while it grows to form a uniform mono-crystalline ribbon 18.

The mono-crystal 18 is placed on support 32, and has an upper surface that lies in a horizontal plane. A silicon wedge 30 of the mono-crystal 18 and wedge of liquid material 28 lays directly over a formation portion 22 of the crucible 12 with the nucleating tip 94 of mono-crystal 18 over the flange and having a thick end of the wedge adjacent the RF electrode 42. This wedge 30 represents the mono-crystal formation front for the crystal 18 that floats on the surface of the molten silicon 14 and is supported by wafer support 32. The mono-crystal 18 is electrically insulated from the wafer support 32 by layer 24 of material such as boron nitride, which provides thermal conduction between the silicon sheet and the supporting associated heaters.

The apparatus 10 for forming a crystalline ribbon from source material has first and second heating electrodes 42, 44 and the plurality of heaters 20 associated with a crucible 12 configured to hold molten silicon. The crucible 12 has a formation portion 22, having a flange member 80 that supports and holds liquid silicon between the flange 80 and the mono-crystal 18. The flange 80 comprises a textured surface 82 configured to hold liquid silicon and reduce turbulence of liquid silicon flowing over the surface.

Formation of the mono-crystal 18 is initiated by a process where a seed of mono-crystalline material is positioned on the surface of molten silicon above the formation portion 22 and allowed to grow. A pulling mechanism 40 attached to the seed crystal is controlled to move the ribbon away from the nucleating tip 94 position and off the molten silicon. Similarly, when processing other materials, the use of like material for the supports or other elements is advantageous, although silicon may be used for processing materials of lower melting points.

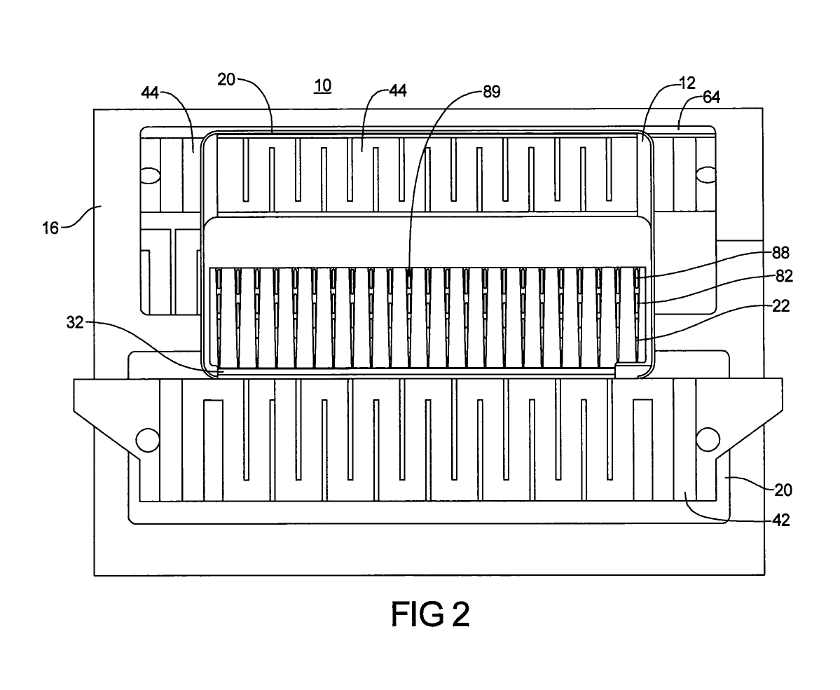

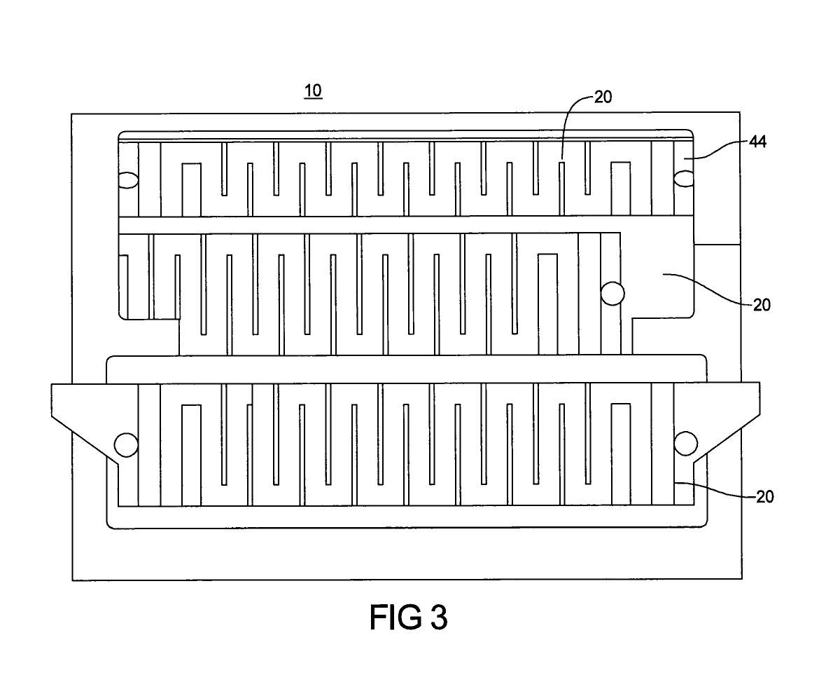

As best seen in FIGS. 1-3, beneath the mono-crystal 18 film of source material is one of a pair of spaced primary laminar ensemble electrodes 42 and 44. Electrode 44 is situated generally on either side of the wedge of liquid 28. The first electrode 42 is parallel to the mono-crystal 18 and is spaced apart from a lower surface 50 and wedge 30 of the mono-crystal 18. The second electrode may be angled with respect to the lower surface 50 of the mono-crystal 18 and is capacitively coupled to the first electrode 42. The electrodes 42, 44 are separated from the molten silicon by a layer material such as boron nitride.

The electrodes 44 have a lower plate of a material such as boronnitide, a central plate 54 of a metal such as molybedenum, and an upper dielectric layer 56 such as silicon nitride for capacitively coupling. The central plate 54 is connected to a terminal of a radio frequency voltage source 58. The electrode 42 has a similar structure and its upper electrode is connected to another terminal of voltage source 58. Thus, the pair of electrodes 42, 44 couple RF energy into the film mono-crystal 18 for resistance heating of the wedge of liquid material 28 immediately adjacent to the silicon wedge 30. In this regard, the electrodes 42, 44 are configured to provide the heat of fusion necessary to maintain the tip of the wedge 30 in a liquid state during processing. Because of the nature of the electronic circuit between the plates 42, 44, the current varies from one side of the wedge 30 to the tip, with the amount of current being increased along the distance of the wedge 30 to the tip. In this regard, the RF source is driven in a manner that the effective strength of the field changes the current along the length of the wedge 30. By adjusting the field using a controller (not shown), the position of the forming edge of the single crystal at the wedge 30/liquid wedge 28 interface can be modified.

A heater 20 is mounted below the electrode 42 and thermally coupled to and electrically isolated from the electrode 42 by a layer 66 of material, such as boron nitride. This heater functions to maintain the mono-crystal 18 at a temperature at or just below its melting point. The rate of in-flow of replenishment material can be controlled by the RF power so the flow is consistent with the rate of ribbon growth maintaining the location of the wedge 30/liquid wedge 28 interface.

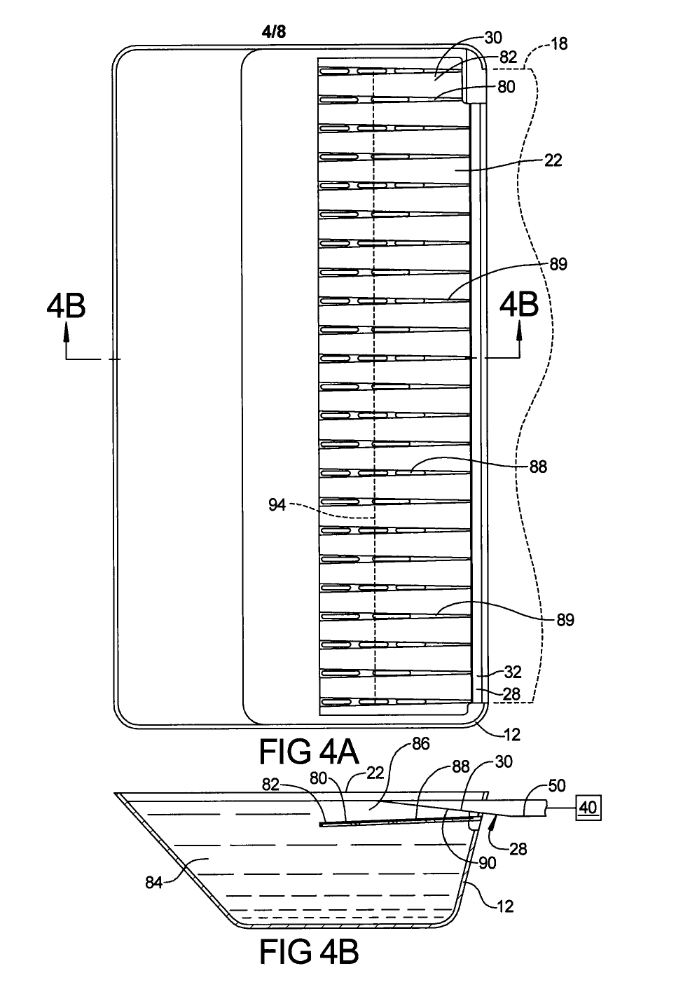

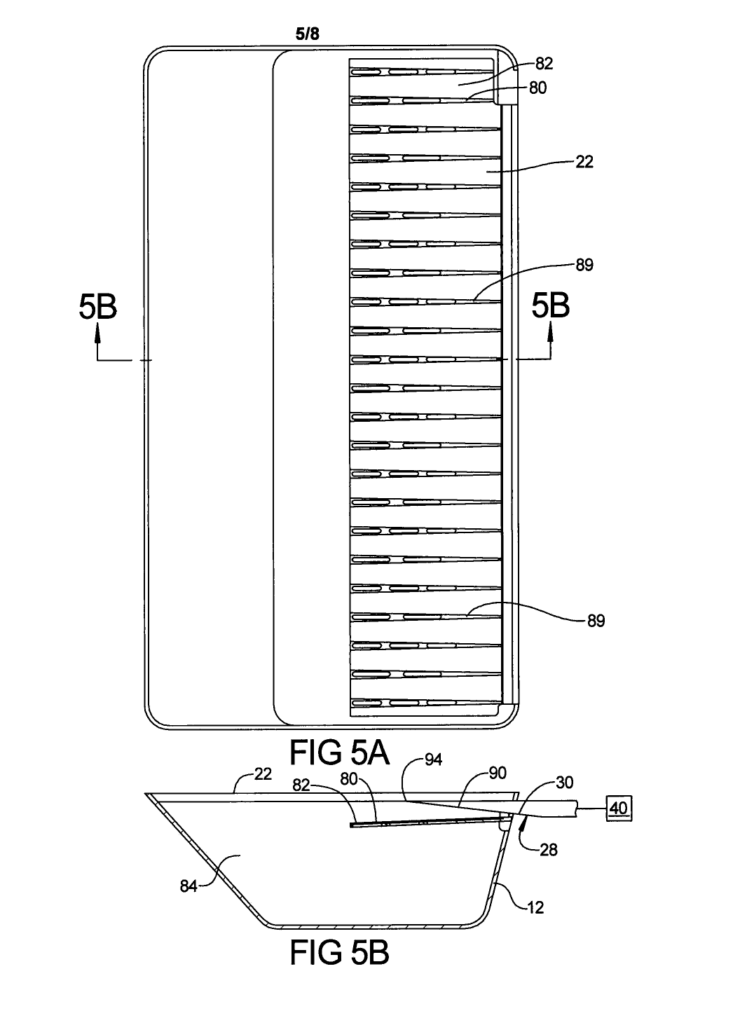

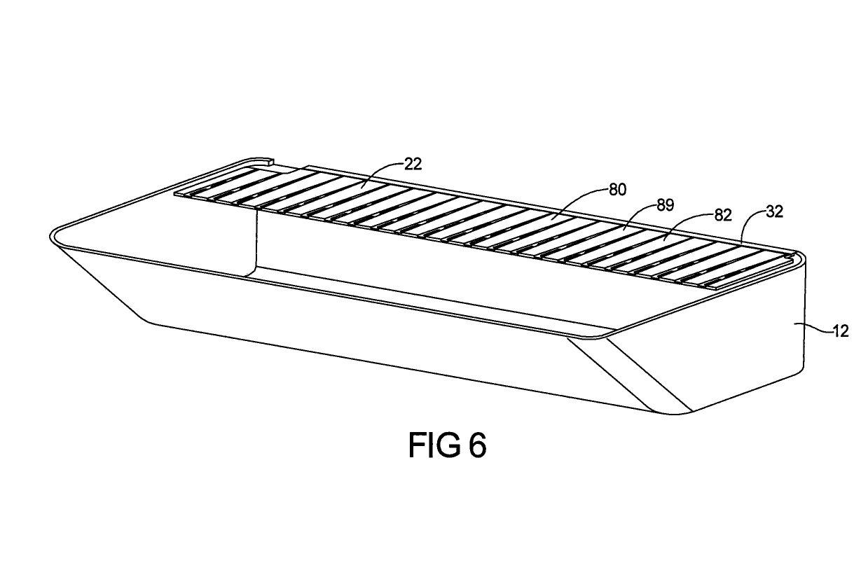

Another embodiment is expressed in FIGS. 4a-6 wherein the formation portion 22 of the crucible 12 is shown. FIGS. 4a and 4b represent top and side views of a crucible with liquid silicon and floating mono-crystal 18, according to the present teachings. FIGS. 5a and 5b represent top and side views of a crucible according to the present teachings having the liquid silicon removed. The formation portion 22 has a flange member 80 that supports and holds the liquid silicon being selectively heated by the first set of electrodes 42, 44. The flange member 80 has a surface 82 that generally faces the lower surface of the mono-crystal 18. This slightly angled surface is texturized so as to allow the full wetting of the surface 82 with the molten silicon. Formed on the surface 82 can be a plurality of through holes that fluidly couple liquid silicon from the pool of liquid silicon 84 with liquid silicon 86 disposed between the surface 82 and the mono-crystal 18. It is envisioned that the texturization and through holes 88 can also be formed on the surface of a portion immediately adjacent to the wedge 30. As seen, the texture can be associated with grooves 89 formed in the surface 82. It should be noted that due to the surface tension of the liquid silicon 84, flow through the through holes 88 is constrained or restricted.

The texturization and through holes 88 are configured to allow the turbulent free flow of the liquid silicon over the surface 82, thus allowing improved formation of the mono-crystal 18. In this regard, as the crystal is slowly withdrawn out of the heated zone, the current from the electrodes 42, 44 allows the formation of the wedge 30 into a planar mono-crystal member generally perpendicular to the wedge 30/liquid wedge 28 interface. Fluid is constantly being replenished from the pool of liquid silicon into the liquid silicon 86 disposed between the surface 82 and the mono-crystal 18. The texturization and through holes 88 provide a liquid surface of material for the incoming silicon to flow over the flange surface 82, thus reducing turbulent flow. It should be noted the texturization need not provide a source of liquid silicon to the space between the surface 82 and the mono-crystal 18.

The heaters 20 may be constructed and operated in accordance with known principles as set forth in the two part paper, Asselman and Green, Heat Pipes, Philips tech Rev. 33, 104-113. 1973 (No. 4) and Philips tech Rev. 33, 138-148, 1973 (No. 5) with the added feature of using the isothermal body as an auxiliary heat source or heat sink. The active working fluid is preferably bismuth or lithium and may be combined with an inactive gas such as argon. The application of the heaters or coolers to the ribbon growing process takes advantage of the high-speed convective ability of the coolers to maintain a uniform temperature along its length and maintain a constant temperature for varying heat flux. The particular temperatures to be used depend on several parameters such as the type and amount of material between the ribbon or melt and the heat sink and the rate of crystal growth.

The operation is initiated by placing on the fluid surface a film of seed material having the desired crystal orientation. The electrodes 20 are heated to 1400° C. to bring the temperature of the seed material to 1400°, and then the electrodes 42 or 44 are energized by RF or DC current to further raise the ribbon temperature to 1405°. The melt zone 90 is established by then applying the RF energy to the electrodes 42 and 44 to bring the selected portion of the ribbon up to the melting point, 1410°, due to resistance heating by the current flow through the liquid silicon. The cooler 102, which has an angled reflective surface, maintains the cooling mode to remove heat from the growing ribbon. The angled reflective surface, which is angled at an angle greater than about 45°, has a surface reflective to infrared light. The angle can be adjusted depending on desired heat reflection to adjust system parameters. When stabilized, thermal gradient will remain uniform from the highest melt temperature at the electrode 44 to the lowest crystal temperature at the heat sink 102. After stability has been attained, the crystal growth mode is entered by pulling the ribbon and maintaining the temperature gradient throughout the growth zone of ribbon. The heat of fusion that must be provided to the growth zone and extracted from the growing crystal depends on the volume of the ribbon and the rate of growth determines the rate of heat extraction.

Throughout the steady state operation, two conditions are desired. First, the interface of the electrodes 42, and the melt 14 is an isothermal plane maintained just above the melting point of the silicon source material. A second heat flux from the solid melt interface 30 determines the rate of solidification controlled in accordance with the volume rate of ribbon growth.

Steady state operation occurs after the system stabilizes upon start-up. The melting of the replenishing pool is begun and is regulated to match the ribbon growth to replenish the melt. The pulling mechanism 40 advances the ribbon as soon as the molten replenishing material enters the melt zone. The ribbon growth occurs essentially perpendicular to the wedge 30/liquid interface, and the ribbon is pulled axially. This allows fast pulling speed at a low crystal growth rate because growth is taking place over a large surface area and growth is substantially perpendicular to the pulling direction.

Each heater 20 serves as a heat clamp, providing a constant and uniform temperature substantially unaffected by variations in heat flux. A uniform heat flux between the heaters and the plane to be controlled is maintained by continuous thermal sensing so that isothermal planes can be established. For example, the heating electrode 42 and the boron nitride layer 46 between the heater and the top surface of the mono-crystal 18 afford a single valued temperature gradients so that the electrode/melt interface has a uniform temperature.

The capacitive characteristic of the electrodes 42, 44 assures a variable current density is passed from the electrodes 42, 44 into the material being melted so that the whole width of the mono-crystal 18 is subject to variable heating. The RF impedance of the silicon nitride dielectric layer of electrode plates 42, 44 permits the plates to serve as a capacitor yet the relatively high DC resistance at 1400 degrees centigrade discourages lateral current flow in the plates that might increase current to film regions offering a lower path of resistance. Current flow in the formed sheet is inhibited by the resistivity of the silicon mono-crystal 18 which is higher than that of liquid silicon wedge 28. Because of the variable heating current density and the uniform surrounding temperature controlled by the heaters 20, the thermal gradients are uniform across the melt zone and wide ribbons can be produced.

The nucleating tip 94 of the wedge 30 is maintained within the formation portion 22 above the surface 82 to prevent or reduce the formation of dendrites or other crystalline structures that would convert the mono-crystal into poly-crystal. The heat removal from the wedge 30 and liquid wedge 28 is sufficient to cause freezing at the melt interface to thereby cause ribbon growth. The shape of the melt zone is determined in part by properties of capacitive coupling and by the difference in electrical conductivity between the solid and liquid states of the silicon: the liquid conductivity is 30 times greater than the solid conductivity. As a result, the current prefers to flow in the liquid and the interface between the liquid silicon and the ribbon wedge 30 can be sharply controlled. After the melt profile is established, only low power is required to maintain the melt zone. The growth interface is inherently stable because the liquid electrical and thermal conductivities are much larger than the solid and small changes in melt thickness will alter the resistance to return the interface to its stable position. During the crystal formation, impurities are rejected by the crystal and tend to concentrate in the liquid between the flange and the mono-crystal 18. However, the melt below the growing ribbon is moving with the ribbon as it grows. The flow of the melt exceeds the diffusion rate of the impurities in opposition of the flow which leads to the effective capture of the impurities in the ribbon as it exits the growth zone.

The high electrical conductivity ratio for silicon results in a wedge 30 angle of only about 2°. The flange member 80 below the mono-crystal 18 is provided with a similar but negative angle to the wedge 30. The thickness of silicon across the width of the ribbon wedge 30, and the mono-crystal 18 will be the same along the region of crystal growth. Thus, the shape and position of the melt zone is determined and the electrodes 42 and 44 are positioned accordingly. Because of crystallization kinematics, contaminants or deposits within the melt are rejected during the crystal formation. Because of this, there is an increased amount of contaminant in the wedge shaped melt 28. When drawn, and finally hardened, these contaminants can plate onto a surface of the crystal.

The first and second heater electrodes 42, 44 capacitively couple electrical energy to the mono-crystal 18. Each planar electrode 42, 44 comprises an electrode that produces a current which passes through the molten silicon and has a supporting heater to provide a uniform base temperature and having a cooler or heat sink held at a constant temperature to provide for crystal growth. The cooler can have a heat source at one end, a heat sink at the other end and a main body having a constant uniform temperature gradient, and the main body is in thermally conductive relation to the ribbon, and wherein the heat source and the heat sink each comprise a constant temperature bath including a partially molten material having a melting point at the said constant temperature. A controller (not shown) coupled to a cooler is provided for removing heat from the crystalline ribbon of material in a direction substantially perpendicular to the plane of the ribbon to effect ribbon growth.

To form the silicon ribbon from a crystalline ribbon source, the system floats a silicon crystal on a bed of molten silicon. The temperature of the crystal silicon is brought to the melting point of the silicon material, the system floats a silicon crystal on a bed of molten silicon. The silicon crystal is heated with a first heater, electrode 42 having a plate defined along the silicon for initially heating a portion of the material and subsequently stabilizing the temperature surrounding the silicon crystal. The temperature of the molten silicon is maintained with a second heater for melting the liquid silicon material. Selected radio frequency electrical currents at between in the range of 1 to 10 megahertz pursuant to the relationship X=(2/ωμσ)^{0.5} ln(I₀/I);

where x=the desired ribbon thickness ω the frequency μ is the permeability of free space and σ is the conductivity are capacitively coupled into the material causing a portion of the silicon crystal, depending on the frequency selected, to also melt along a wedge-shaped zone. Heat from the melted silicon crystal of material is removed in a direction substantially perpendicular to the plane to effect silicon crystal growth.

When a single crystal silicon seed is placed unconstrained on a melt, the level of the solid surface will lie parallel to and just above the melt surface. The emissivity of the solid surface is twice that of the melt. However the thermal conductivity of the melt is about three times that of the solid. Hence to equilibrate the heat loss at the tip, the ribbon will tend to be modified so the conductivity of the solid plus the emissivity heat loss from the solid will tend to equal the conductivity of the melt plus the emissivity heat loss from the melt. Without relative motion between the solid and the melt the shape of the solid melt interface will tend to become curved. Since the melt is denser than the solid at the melting point, the level of the top of the solid and that of the melt will tend to become more nearly equal. However, the contact angle of the melt to the solid interface has been determined to be just 11 degrees. As the thickness of the solid at the interface surface is decreased there will remain a slight step from the melt top to the solid top unless the solid is vertically constrained as melt is added. To satisfy all of the restraints above, the growth surface of the solid should not remain vertical but tilt about 11 degrees away from the body of the melt and toward the lower surface of the solid as the interface develops. These conclusions remain valid if the Pec'let number remains below 10⁻² or smaller and the radius of the nucleating tip is sufficiently great to avoid capillary effects. Previous experimental results support these conclusions.

When the solid-melt interface equilibrates the solid and the melt will be at the melting point. As the heating in the growth zone begins using the RF coupled electrode, a gradient in the horizontal current is established. Because the electrical conductivity of the melt is five times greater than that of the solid, a sloping solid-melt interface will be developed as the heat of fusion in the growth zone is supplied to the solid. The equilibrium will be established again when the additional heat applied to the solid is removed through the heat sink and the system temperature is stabilized. Pulling of the ribbon may begin finally reaching the pull rate commensurate with the desired thickness. The system can further be used to form a continuous ribbon of crystal for use as a solar cell which is cut into desired lengths. Each ribbon may have an exterior surface which can be smoothed using appropriate etchants or physical material removing mechanisms such as an abrasive. Selective deposition of connections onto the surface can be made using known techniques such as PVD or CVD, to product contacts for an AC or DC output at selected voltages and currents.

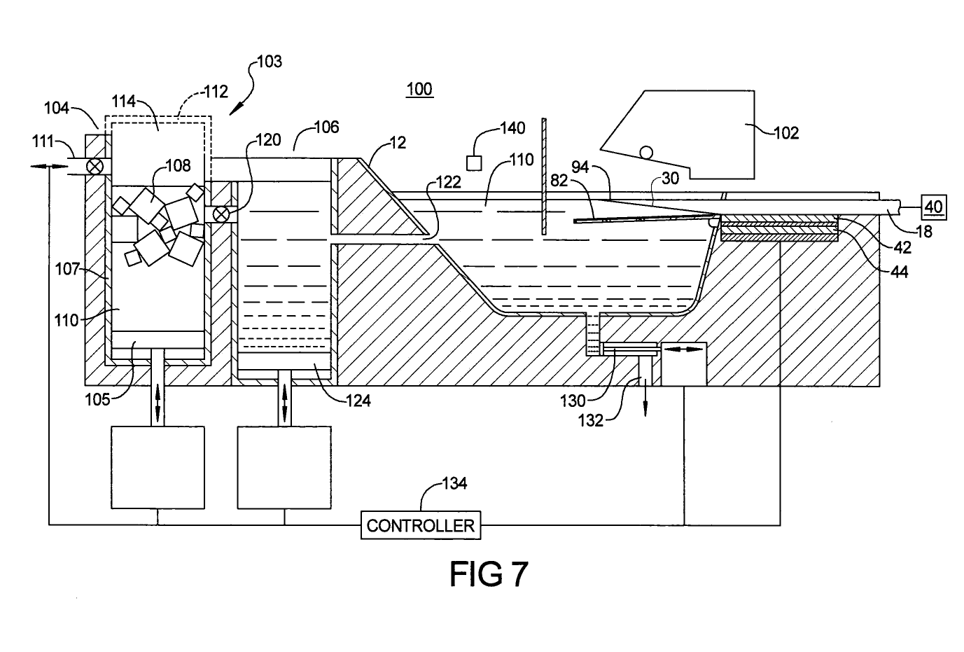

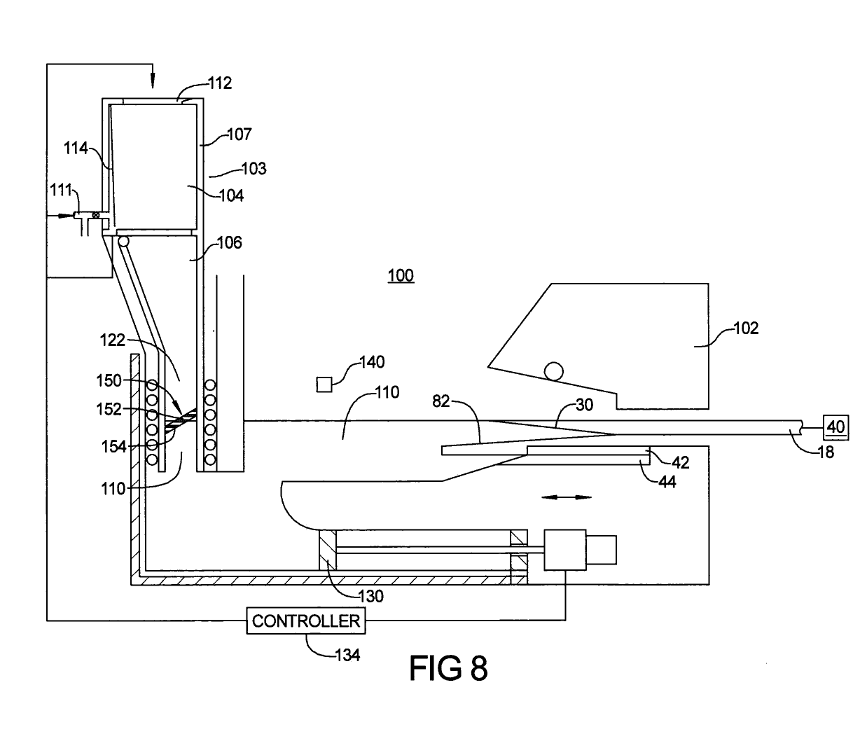

FIGS. 7 and 8 represent sectional views of the apparatus 100 according to the present teachings. The apparatus comprises a crucible 12 and associated heating and cooling elements as shown in FIGS. 1-6 above. Associated with the crucible 12 is a silicon supply system 103. The silicon supply system 103 can be formed of a silicon pre-processer 104 and a silicon supply 106. The silicon pre-processer 104 has a vessel 107 which converts solid silicon 108 into liquid silicon 110. The vessel 107 has an operable top or cover 112 which allows the addition of solid silicon 108 into a chamber 114 defined by the vessel 107. The vessel 107 can have a plurality of heaters (not shown) which bring the solid silicon 108 up to its melting temperature to convert the solid silicon 108 to liquid silicon 110. A piston 105 can be used to assist in the flow of liquid silicon 110 into the silicon supply 106. The solid silicon is further melted to controllably add molten silicon to the melt below. To avoid serious disturbance of the melt level, an angled barrier is introduced in the zone 106 to prevent the solid entering the chamber by splashing or disturbing the growth zone. Preferably, the surface can be angled at 45 degrees, with the through bores having an axis generally parallel to the surface of the melted silicon. The barrier is configured to reduce extensive initial contact of the silicon with the channel area 106. As needed, the barrier will permit the melted silicon to continuously flow into the growth zone in a controlled manner. Optionally, movable or vibratory members (not shown) may be used to dislodge solid silicon material from the region associated with the angled surface.

Associated with the vessel 107 is a valued inlet 111 which allows for the application of a vacuum to the vessel 107 to allow the degassing of the solid and liquid silicon 108, 110. After degassing, an inert gas such as Argon can be applied over the liquid silicon 110. It should be appreciated that the pressure of the Argon or inert gas can be stabilized to ambient pressure at the melting temperature of silicon. To couple the degassed liquid silicon 110 into the silicon supply 106, a valved passage 120 is provided. The valved passage 120 allows the flow of liquid silicon 110 into the silicon supply 106 using gravity or pressure.

The silicon supply 106 provides degassed silicon 110 into the crucible 12 through a spillway 122. The height of the liquid silicon 110 in the silicon supply 106 can be affected by a movable piston 124. As previously described, the level of liquid silicon 110 within the crucible 112 should be maintained. This level can be maintained using various techniques such as by adjusting the piston 124 associated with the silicon supply 106. The levels can further be maintained using a second piston 130 associated with an aperture 132 defined in the bottom of the crucible 12. The pistons 124, 130 are associated with a controller 134 which regulates the flow of liquid silicon from the silicon pre-processor 104 through the silicon supply 106 and into the crucible 102.

In the event of an accidental power shut down, the second piston 130 is biased away from the aperture 132 to allow for the emergency release of the liquid silicon 110 out of the crucible 12 to prevent damage to the crucible 12 due to expansion of the silicon caused by the cooling and subsequent phase transformation of the liquid silicon 110. This bias can be formed by silicon fluid pressure, springs or backup powered actuators (not shown).

As the pulling of a seed crystal begins, a thinner section of the solid moves over the growth zone heater which provides for additional heat extraction and growth of the solid along the solid melt interface. As the heat of fusion is supplied in the growth zone, there will also be additional heat supplied to the surface of the melt source. To maintain system stability, this additional heating will be compensated for by reducing the other heating means to equilibrate the temperature throughout the non-growth areas of the system. For this system to operate effectively the interactive elements of the process must be controlled. The principal and interactive elements are:

The controller 134 controls several aspects of the device. By adjusting the controllable features, properties of the crystal ribbon can be affected. These include crystal ribbon thickness, the ambient temperature of the system, the location of the nucleating tip, control of the meniscus for the tip, as well as controlling crystal orientation. To control the crystal ribbon thickness, the nucleating tip location can be controlled using an optical sensor with feedback to the controller 134. Thickness can also be controlled by adjusting the current, voltage or frequency to the RF heaters. Additionally, the amount of cooling can be regulated by changing the flow of coolant through the coolers.

The location of the nucleating tip can be controlled by changing the ambient temperature of the system. This change can be accomplished using primary heaters, source heaters, heat sink temperatures or the RF heaters 42, 44. Additionally, the nucleating tip location and shape can be controlled by melt surface radiation, laminar flow of the liquid silicon, the pull rate for the crystal as well as three dimensional heating patterns and control of the crystal orientation.

The exit meniscus of the crystal can be controlled by having the controller adjust the pull rate of the crystal, RF frequency and current or voltage control of the heaters. Additionally, the controller 134 can control heat sink temperature. By maintaining and monitoring impurity and doping levels, properties used in the formation of junctions can be regulated.

To maintain control of the liquid level in the crucible 12, light sensors 140 connected to the controller 134 can determine the liquid level. To adjust the liquid level in the crucible 12, the pistons 124 and 130 can be controlled in response to the sensor inputs.

The crystal thickness can be adjusted using the controller 134 by varying the RF heater current or frequency. Additionally, the thickness of the crystal can be adjusted by controlling the heat sink temperature. In this regard, the thickness can be adjusted by three-dimensional control of the temperature about the nucleating tip, melt surface, radiation absorption, laminar flow at the solid liquid interface. The controller 134 can additionally monitor the crystal orientation by watching reflected energy such as light or x-rays associated with a formed crystal using optical methods. The exit meniscus for the system can be controlled by the controller 134 by adjusting the pull rate, the RF current, the size and shape of the heat sink temperature control zone as well as impurity levels.

In this application, including the definitions below, the term controller 134 may be replaced with the term circuit. The term module may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term code, as used above, may include software, firmware, and/or microcode, and may refer to programs, routines, functions, classes, and/or objects. The term-shared processor encompasses a single processor that executes some or all code from multiple modules. The term group processor encompasses a processor that, in combination with additional processors, executes some or all code from one or more modules. The term-shared memory encompasses a single memory that stores some or all code from multiple modules. The term group memory encompasses a memory that, in combination with additional memories, stores some or all code from one or more modules. The term memory may be a subset of the term computer-readable medium. The term computer-readable medium does not encompass transitory electrical and electromagnetic signals propagating through a medium, and may, therefore, be considered tangible and non-transitory. Non-limiting examples of a non-transitory tangible computer readable medium include nonvolatile memory, volatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. As used herein, the phrase at least one of A, B, and C should be construed to mean a logical (A or B or C), using a non-exclusive logical OR. It should be understood that one or more steps within a method might be executed in different order (or concurrently) without altering the principles of the present disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An apparatus for forming a crystalline ribbon of molten silicon
comprising:
a crucible configured to hold molten silicon, the crucible having a formation portion, said formation portion having a flange member that supports and holds molten silicon between the flange and a portion of the crystalline ribbon floating on the molten silicon;
a feed mechanism configured to feed molten silicon into the crucible at a controlled rate, the feed mechanism defining a chamber configured to melt solid silicon;
a first heater electrode comprising a plate positioned adjacent to the ribbon in thermally conductive relation to the source material and means for controlling a temperature just above a melting point of the molten silicon for initially heating the material and subsequently stabilizing the temperature adjacent to the ribbon at a melt solid interface;
a second heater for melting the molten silicon material configured to maintain the temperature of the molten silicon at its melting temperature, including a pair of spaced planar electrodes capacitively coupling radio frequency electrical currents into the molten silicon and imparting a heat of fusion to the molten silicon to a ribbon tip location causing a portion of the ribbon of material to melt along a zone;
a controller configured to control the removal of heat from molten silicon material in a direction substantially perpendicular to the surface of the molten silicon to effect crystal growth and control the feed mechanism; and
a mechanism for causing relative motion parallel to the plane between the ribbon and the heater.

2. The apparatus as defined in claim 1, further comprising a vacuum source coupled to the chamber configured to remove gas from the chamber.

3. The apparatus as defined in claim 2, further comprising a source of inert gas coupled to the chamber.

4. The apparatus as defined in claim 1, further comprising a second chamber configured to hold molten silicon disposed between the chamber and the crucible.

5. A method of forming a crystalline ribbon from molten silicon comprising:
melting solid silicon in a first chamber;
floating a silicon crystal on a surface of a bed of molten silicon;
heating the silicon crystal with a first heater comprising a plate defined along the silicon crystal in capacitive conductive relation to the silicon crystal;
controlling a temperature of the molten silicon to a temperature at a melting point of molten silicon for initially heating the material and subsequently stabilizing the temperature surrounding the silicon crystal;
maintaining the temperature of the molten silicon with a second heater for melting the molten silicon material;
capacitively coupling radio frequency electrical currents into the molten silicon causing a portion of the silicon crystal to melt along a zone; and
removing heat from the silicon crystal in a direction substantially perpendicular to the surface of the liquid silicon to effect silicon crystal growth of the silicon crystal;
causing relative motion parallel to the surface of the molten silicon between the ribbon and the heater; and
feeding molten silicon into the crucible from the first chamber at a defined rate.

6. The method as defined in claim 5, wherein removing heat from the silicon crystal comprises controlling a temperature below a melting point of the silicon material.

7. The method as defined in claim 5, comprising controlling the rate of molten silicon being fed from the first chamber to the crucible.

8. The method as defined in claim 5, wherein capacitively coupling radio frequency electrical currents into the molten silicon causes a portion of the silicon crystal to melt along a zone capacitively coupling radio frequency electrical currents into the layer of molten silicon.

9. The method as defined in claim 5, further comprising controlling the level of molten silicon by moving at least one piston fluidly coupled to the molten silicon.

10. An apparatus for forming a crystalline ribbon from molten silicon
comprising:
a crucible configured to hold molten silicon, the crucible having a formation portion, and a feed mechanism configured to feed molten silicon into the crucible at a predetermined rate;
a first heater electrode positioned a distance from moving molten silicon in capacitive conductive relation to the moving molten silicon and having a controller for controlling a temperature just above a melting point of the moving molten silicon for initially heating moving molten silicon and subsequently stabilizing the temperature surrounding a wedge portion of the crystalline ribbon;
a second heater electrode displaced from and non-parallel to the first heater electrode, positioned a distance from the moving molten silicon in capacitive conductive relation to the moving molten silicon and the first heater electrode, the second heater electrode configured to impart a heat of fusion to the moving molten silicon along and at a ribbon tip causing a ribbon of material to melt along a zone;
the controller configured to control application of RF energy to the moving molten silicon by the first and second electrodes and control the level of the molten silicon in the crucible; and
a mechanism for causing relative motion parallel to the surface of the molten silicon between the ribbon and the heater.

11. The apparatus as defined in claim 10, further comprising a surface defining chamber having a movable piston configured to adjust the level of molten silicon in the chamber.

12. The apparatus as defined in claim 11, wherein the crucible comprises a second piston fluidly coupled to the molten silicon.

13. The apparatus as defined in claim 12, wherein the application of RF energy is the application of application of RF energy to a heat of fusion to the moving molten silicon.

14. The apparatus as defined in claim 13, wherein the application of RF energy is the application of RF energy at between about 10 to 20 Mhz.

15. An apparatus for forming a crystalline ribbon from a source of molten silicon comprising:
first and second heating electrodes;
a crucible configured to hold molten silicon, the crucible having a formation portion, said formation portion having a flange member that supports and holds the molten silicon between the flange and the crystalline ribbon, the level of the molten silicon being controlled by a movable piston;
the first heating electrode comprising a temperature regulator in thermally conductive relation to the ribbon for heating a wedge portion of the ribbon and subsequently stabilizing the temperature surrounding the wedge portion of the ribbon;
the second heating electrode for maintaining the temperature of the molten silicon, wherein second heater electrode is in capacitively conductive relation with both the first heating electrode and the molten silicon to provide a capacitive path from the first heating electrode past the crystalline ribbon;
a controller coupled to a cooler for removing heat from the crystalline ribbon in a direction substantially perpendicular to a surface of the molten silicon to effect ribbon growth and to the piston; and
a mechanism for causing relative motion parallel to the plane between the ribbon and the first heating electrode; the mechanism being controlled by the controller.

16. The apparatus as defined in claim 15, wherein the first and second heating electrodes capacitively couple electrical energy to the ribbon and each heating electrode comprises an electrode that produces a current distribution in contact with the molten silicon.

17. The apparatus as defined in claim 15, wherein the first heating electrode is positioned relative a cooler having a heat sink maintained at a constant temperature.

18. The apparatus as defined in claim 16, wherein the first heating electrodes produce a varying electronic current through the molten silicon.

19. The apparatus as defined in claim 15, wherein the flange member defines a plurality of through apertures.

20. The apparatus as defined in claim 15, wherein the flange comprises a textured surface configured to hold molten silicon and reduce turbulence of molten silicon flowing over the surface.
